(19) United States
(12) Patent Application Publication
(10) Pub. No.: US 2009/0097330 A1
(43) Pub. Date: Apr. 16, 2009

(54) Fuse latch circuit and fuse latch method

(75) Inventor: Hideyuki Yoko, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/285,685

(22) Filed: Oct. 10, 2008

(30) Foreign Application Priority Data
Oct. 12, 2007 (JP) 2007-266453

(51) Int. Cl. G11C 7/00; G11C 11/21

(52) U.S. Cl. 365/189.05; 365/189.15

(57) ABSTRACT

A fuse latch circuit starts a precharge operation for reading out a state of a fuse element when receiving an external command which is a command to reset an operation mode register (MRS reset command) after power-on, and reads out and latches the state of the fuse element after completion of the precharge operation.

This application is based upon and claims the benefit of priority from Japanese Patent Application No. 2007-266453, filed Oct. 12, 2007, the disclosure of which is incorporated herein in its entirety by reference.

### BACKGROUND OF THE INVENTION

1. Field of the Invention

This invention relates to a fuse latch circuit and a fuse latch method for detecting a state of a fuse element in a semiconductor device.

2. Description of the Related Art

A semiconductor device typically uses a fuse element to store information specific to the semiconductor device in the semiconductor device. Japanese Laid-Open Patent Publication No. 2004-246958, for example, describes a semiconductor device which is designed to detect a state of a fuse element reliably by reading out the state of the fuse element based on a reset signal instructing a first reset operation after power-on.

### SUMMARY OF THE INVENTION

Referring to FIG. 1 and FIG. 2, problems to be solved by this invention will be described. FIG. 1 is a timing chart of a fuse latch circuit used for explaining the problems to be solved by this invention. FIG. 2 is a circuit diagram showing a configuration example of the fuse latch circuit. The term “fuse latch circuit” as used herein means a circuit for reading and latching a state of a fuse element formed on a semiconductor device in response to a predetermined control signal. The state of the fuse element, that is, the state in which the fuse element is short or open circuited can be set for example by using a laser or the like in a manufacture process of the semiconductor device.

FIG. 1 is a timing chart showing operation of a fuse latch circuit in a synchronous memory chip. The timing chart illustrates a relation between clock signal CK and a laser fuse setting period which is started in response to a MRS command (mode register set command) externally input and lasts until the state of the fuse element is detected and latched.

The fuse latch circuit has to be set before an ACTV (active) command is input to a memory chip. Fuse information is set by the MRS command signal or a power-on signal generated during power-on. An internal circuit is unstable particularly during generation of the power-on signal. Therefore, a major method taken for setting the fuse information is the use of the MRS command that is a command for setting a memory operation mode. When using the MRS command to set the fuse information, the fuse information must be set to satisfy tMRD (mode register set cycle time) as an AC (alternate current) specification. For example, in a LPDDR2 (Low Power Double Data Rate 2) memory, the tMRD is two clock cycle (2*tCK).

FIG. 2 shows an example of a fuse latch circuit. The fuse latch circuit shown in FIG. 2 is a circuit for latching the fuse in its disconnected state. The fuse latch circuit is composed of NMOS (N-channel metal-oxide semiconductor) transistors 31 and 32 the sources of which are connected to a fuse element FUSE and the drains of which are connected to each other at a node A, PMOS (P-channel metal-oxide semiconductor) transistors 33 and 34 the drains of which are connected to the drains of the NMOS transistors 31 and 32, and an inverter 35 connected between the drains and gates of the NMOS transistor 32 and PMOS transistor 34. In this configuration, a ground voltage VSS is applied to the other end of the fuse element FUSE, a power supply voltage VPREI is applied to the sources of the PMOS transistors 33 and 34, a signal FSET is input to the gate of the NMOS transistor 31, and a signal PREB is input to the gate of the PMOS transistor 33. The input of the inverter 35 is connected to the drains of the transistors 31 to 34 at the node A, and the output of the inverter 35 connected to the gates of the transistors 32 and 34 is connected to an output OUT.

The current drive capacity of the NMOS transistor 31 and PMOS transistor 33 should be sufficiently greater than that of the PMOS transistor 34 and NMOS transistor 32. This means that when the PMOS transistor 33 is turned ON, the node A is precharged to the VPREI level regardless of what state the NMOS transistor 32 is in. When the NMOS transistor 31 is turned ON and if the fuse element FUSE is not disconnected, the node A is dropped to the VSS level regards of what state the PMOS transistor 34 is in. After the transistor 33 is turned OFF and the transistor 31 is also turned OFF, an inverter composed of the transistors 32 and 34 inverts the output of the inverter 35 and inputs the inverted output to the inverter 35. Accordingly, the output of the inverter 35 is latched at a value before the turning OFF of the transistor 31 according to the level of the node A.

The circuit configuration shown in FIG. 2 is designed such that the output OUT is latched to “H” level when the fuse FUSE is not disconnected, whereas the output OUT is latched to “L” level when the fuse FUSE is disconnected. This output signal is used for various controls and comparative determination by a redundancy relieving circuit.

FIG. 3 shows a timing chart for explaining operation of the fuse latch circuit shown in FIG. 2. FIG. 3 illustrates variation in the clock signal CK, the signals PREB and FSET shown in FIG. 2, and current I flowing from the power supply VPREI to the node A. According to the circuit configuration shown in FIG. 2, the signal PREB becomes “L” level in response to the MRS command before the disconnected state of the fuse FUSE is latched, and the node A is once precharged to the VPERI level by turning the PMOS transistor 33 ON. This is done in order to distinguish the levels at the node A when the fuse FUSE is disconnected and not disconnected. A through current I is generated from the power supply VPREI as shown in FIG. 3 during a precharge period when the signal PREB is at “L” level.

After the signal PREB is set to “L” level, a period required to precharge the node A is ensured as a precharge period, and then the signal PREB becomes “H” level after. At this time point, the PMOS transistor 33 is turned OFF. The signal FSET then becomes “H” level for a certain period of time as a fuse information setting period. The NMOS transistor 31 is turned ON when the signal FSET becomes “H” level. Therefore, the potential of the node A becomes the VSS level when the fuse element FUSE is not disconnected. When the fuse element FUSE is disconnected, however, the potential of the node A does not change and remains at the VPREI level. According to this circuit configuration, a period of several nanoseconds is normally required as the period for setting the fuse information, that is, a laser fuse setting period obtained by the adding the precharge period and the fuse information setting period.

As described above with reference to FIGS. 2 and 3, a period of several nanoseconds is required to set the fuse information. On the other hand, in the case of a conventional LPDDR (266@tCK=7.5 ns) memory as shown in FIG. 4A, the data transfer rate is about 266 Mbps, and hence the clock cycle tCK is as low as 7.5 ns. Therefore, it is possible to set the fuse information within the period of tMRD=2*tCK=15 ns. The LPDDR memory thus provides leeway in terms of timing as indicated by a circle in FIG. 4A.

However, LPDDR2 memories have an improved clock frequency in comparison with that of LPDDR memories, and it is determined that the clock frequency in the LPDDR2 (667@tCK=3 ns) memories is standardized to tCK=3.0 ns. Accordingly, in the case of LPDDR2−667, as shown in FIG. 4B, tMRD is 6 ns that is shorter than half the tMRD period of 15 ns in the LPDDR.

Therefore, it will presumably be difficult to set the fuse information within the period of time. This means that, in the case of LPDDR2−667, the tMRD period is too short for a laser fuse setting period, which cuts into the period of the ACTV command as indicated by a circle in FIG. 4B. Additionally, some memories employ a time-division setting method, as a countermeasure against the problem of through current flowing during precharge, in which a fuse latch circuit sets a plurality of fuse elements while shifting the fuse setting periods.

The problem will presumably be more serious in such memories. The above-described LPDDR2 is now being standardized by JEDEC (Joint Electron Device Engineering Council) as a next generation DDR2 version of low power DDR1. It is predicted for the LPDDR2 operating at a higher frequency than the LPDDR that it is difficult to complete reading of fuse information within the tMRD period started by a MRS command. Although the same is true for DDR2, DDR3 and other ordinary high frequency products, these products are provided with a DLL (Delay Locked Loop) circuit and thus fuse information may be set by using a DLL reset command. However, the low-power LPDDR and LPDDR2 are determinately not provided with a DLL circuit for the purpose of reducing power consumption. Therefore, setting fuse information is one of technical problems to be solved in relation to the LPDDR2.

In one embodiment, there is provided a fuse latch circuit comprising a fuse latch generator which, when receiving a command to reset an operation mode register after power-on, outputs a precharge signal to control precharge operation for reading out a state of a fuse element, and a fuse set signal for reading out and latching the state of the fuse element after completion of the precharge operation; and a latch circuit which, after performing the precharge operation in response to the precharge signal, reads out the state of the fuse element and latches that state in response to the fuse set signal.

In another embodiment, there is provided a semiconductor device comprising a fuse element for storing data as non-volatile data, a command decode latch circuit which is supplied with a set command for setting the operation mode register or a reset command for resetting the operation mode register, and outputs a control signal in response to the reset command, and a latch circuit for latching the data stored in the fuse element.

In still another embodiment, there is provided a fuse latch method wherein a precharge operation for reading out the state of a first fuse element is started when a command to reset an operation mode register is input after power-on, and after completion of the precharge operation, the state of the fuse element is read out and latched.

According to the present invention, a fuse latch circuit is started by using, as a trigger, a command such as a MRS reset command to reset an operation mode register after power-on. Fuse information can be latched in a period of time from input of a MRS reset command until input of a MRS command which is a command to set an operation mode in the operation mode register. The duration of time from the input of the MRS reset command to the input of the MRS command is determined to be for example about 1 μs. Thus, a sufficient time margin can be ensured for a conventional laser fuse setting period. This makes it possible to detect and latch the state of a fuse element stably and reliably.

### BRIEF DESCRIPTION OF THE DRAWINGS

FIG. 1 is a timing chart for explaining an example in which a laser fuse setting period is set in response to a MRS command;

FIG. 2 is a circuit diagram showing an example of a fuse latch circuit;

FIG. 3 is a timing chart for explaining operation of the fuse latch circuit shown in FIG. 2;

FIG. 4A is a timing chart for explaining a laser fuse setting period in a LPDDR (266@tCK=7.5 ns) memory;

FIG. 4B is a timing chart for explaining a laser fuse setting period in a LPDDR2 (667@tCK=3 ns) memory;

FIG. 5 is a timing chart for explaining characteristics of an embodiment of this invention;

FIG. 6 is a block diagram showing configuration of an embodiment of this invention;

FIG. 7 is a circuit diagram showing an example of configuration of the fuse latch generator (1) 604 of FIG. 6;

FIG. 8 is a circuit diagram showing an example of configuration of the fuse latch circuit block (1) 605 of FIG. 6;

FIG. 9 is a timing chart for explaining operation of the embodiment of this invention shown in FIGS. 6 to 8; and

FIG. 10 is a timing chart for explaining another embodiment of this invention.

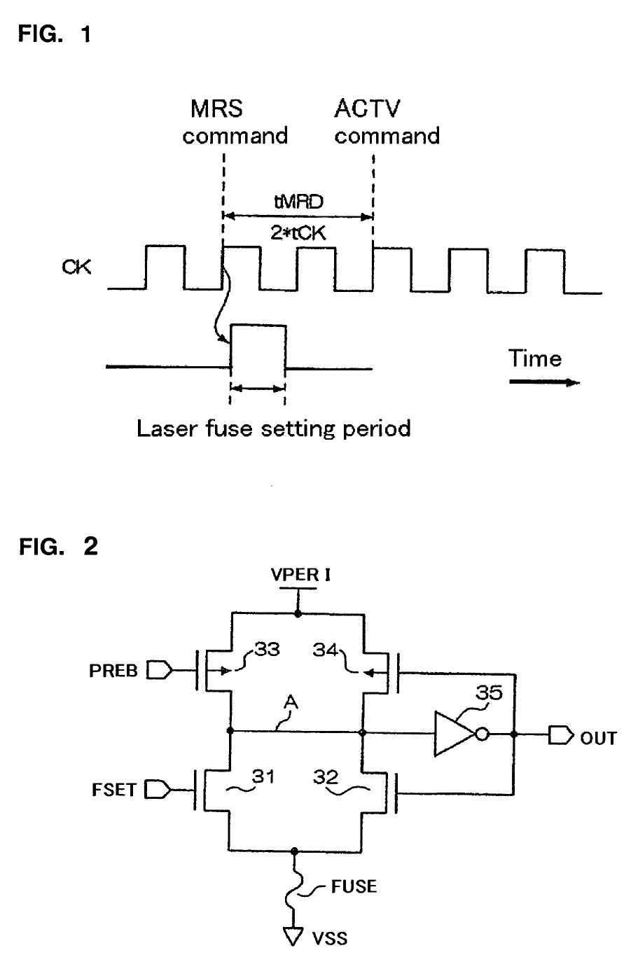

### DESCRIPTION OF THE EXEMPLARY EMBODIMENTS

An exemplary embodiment of a fuse latch circuit according to this invention will be described with reference to the accompanying drawings. The fuse latch circuit of this embodiment can be provided, for example, in a LSI (large-scale integrated circuit) which has a large number of fuse elements and implements various functions, including resetting of an operation mode register by using a MRS reset command. The LSI may for example be a LPDDR2-DRAM (LPDDR2 dynamic random access memory).

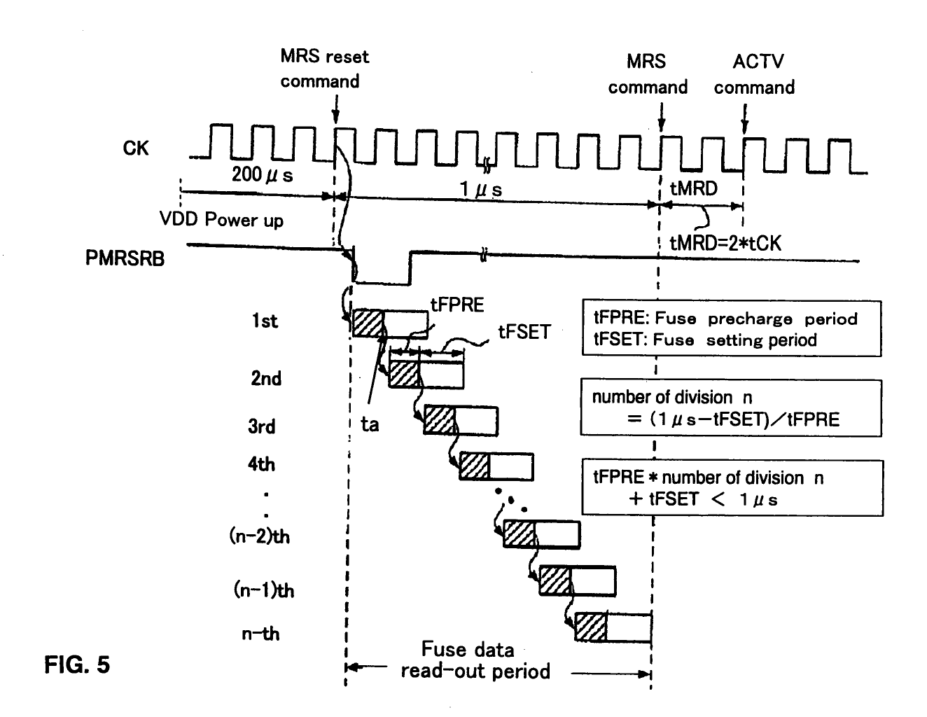

In the first place, characteristics of the embodiment will be described with reference to FIG. 5. The shown embodiment is characterized by how a fuse latch circuit is activated. In other words, it is characterized in that the fuse latch circuit is activated with the use of a MRS reset command. This MRS reset command (mode register set reset command) is a command for resetting a MRS (mode register set) and is to be employed in LPDDR2, for example. Specifically, a principal characteristics of the shown embodiment resides in that the MRS reset command as a new function of the LPDDR2 is used as a trigger to set, in a time division manner, information of the fuse elements during an initial period after the input of the MRS reset command (see FIG. 5).

FIG. 5 shows a timing chart in which a plurality of fuse latch circuits are operated in a time division manner within a fuse data reading period in a semiconductor memory which the present embodiment is applied to. A decode latch circuit (MRS reset) generates a PMRSRB signal when a clock signal CK supplied to the semiconductor memory and a MRS reset command which is a command to reset a memory mode register for setting an operation mode of the memory are input. Being triggered by this PMRSRB signal as a start signal, the plurality of fuse latch circuits are operated in a time division manner, whereby fuse data are read sequentially from the respective fuse latch circuits. The MRS reset command is input after a period required for ensuring build-up of an internal power supply voltage VDD or the like and stabilization of the clock signal has elapsed from build-up of an externally supplied power supply voltage (after a lapse of 200 μs in the example of FIG. 5). Further, after the input of the MRS reset command, a certain waiting period (1 μs period in the example of FIG. 5) is involved until a MRS command (mode register set command) for setting a desired operation mode in the mode register is input.

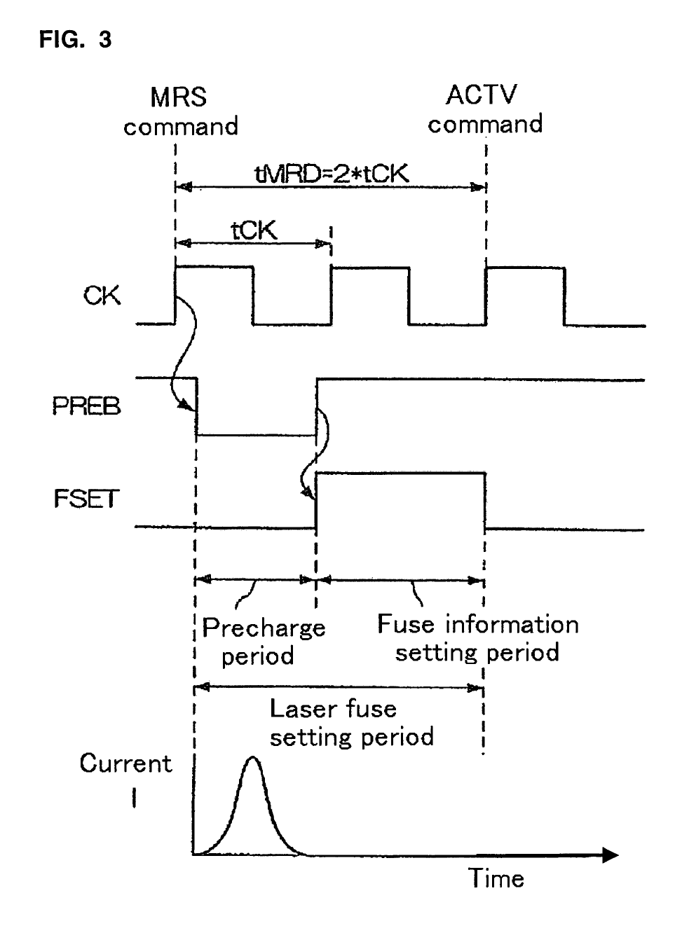

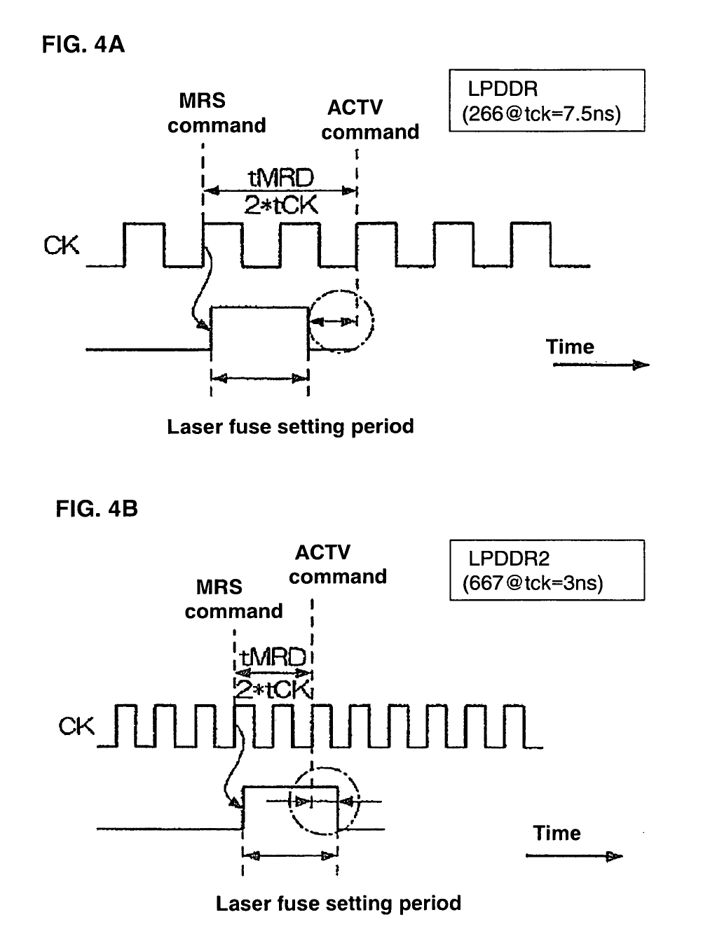

In the shown embodiment, a first time-division laser fuse setting period is started by being triggered by a PMRSRB signal which is a pulse signal assuming “L” level for a certain period of time after input of a MRS reset command. This laser fuse setting period can be divided into a fuse precharge period tFPRE (corresponding to the precharge period in FIG. 3) and a subsequent fuse setting period tFSET (corresponding to the fuse information setting period in FIG. 3). A second time-division fuse precharge period tFPRE is started at the end of the first fuse precharge period tFPRE (at time ta). Therefore, the fuse precharge period tFPRE of the first and second laser fuse setting periods do not overlap with each other. However, there occurs a period in which the first fuse setting period tFSET is performed in parallel with the second fuse precharge period tFPRE and the second fuse setting period tFSET. Third to n-th laser fuse setting periods are also performed in a similar manner.

As shown in FIG. 5, the present embodiment is characterized in that the fuse latch circuit is activated by being triggered by a MRS reset command, so that all the fuse information is latched in a time division manner within a relatively long reset period of about 1 μs from the input of the MRS reset command to the input of the MRS command. Since there is a duration of about 1 μs from the input of the MRS reset command to the input of the MRS command, a large margin can be ensured for a conventional laser fuse setting period (see FIG. 3) started in response to a MRS command. When the time-division method is employed, the fuse precharge periods are arranged such that they do not overlap within each other within the time period of 1 μs (1 μs>n*tFPRE+tFSET). Accordingly, the number of divisions n can be determined and represented by (1 μs−tFSET)/tFPRE.

A fuse latch method for the fuse latch circuit is designed such that when a command to reset the operation mode register is input after power-on, a precharge operation for reading the state of a fuse element is started, and the state of the fuse element is read after completion of the precharge operation, and the fuse element is latched in that state. After completion of the first precharge operation, another precharge operation for reading the state of a subsequent fuse element can be started as a time-division operation.

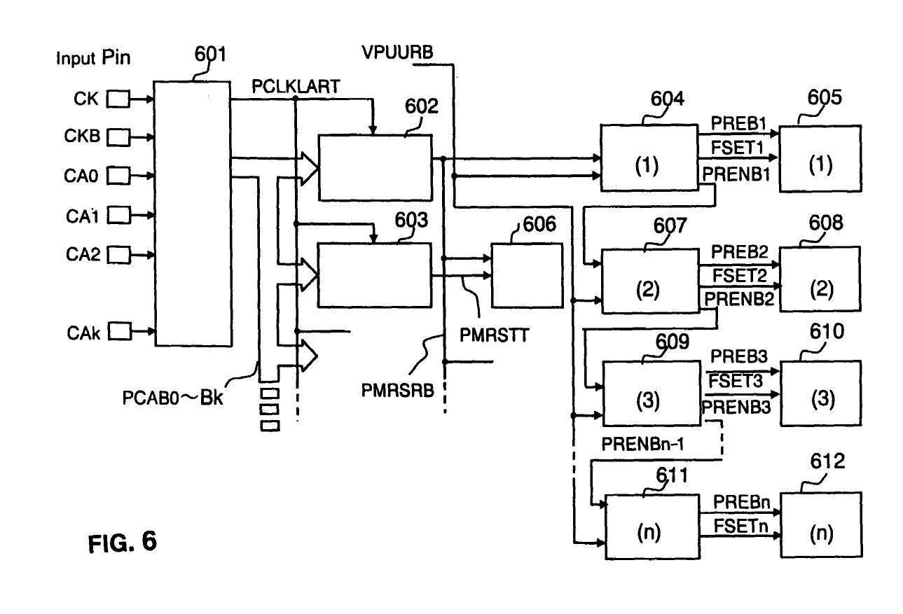

FIG. 6 is a block diagram for explaining a circuit configuration according to the present embodiment. FIG. 6 is a block diagram of a semiconductor device having the circuit configuration according to the present embodiment, in which only blocks of the semiconductor device relating to the circuit configuration of the present embodiment are shown. An input buffer 601 has a plurality of input buffers respectively corresponding to an input pin for receiving clock signal CK, an input pin for receiving clock signal CKB (inverted signal of the clock signal CK), and (k+1) input pins (k is a natural number) for receiving command address signals CA0 to CAk. A command decode latch circuit (MRS reset) 602 decodes inverted output data PCAB0 to PCABk output from the input buffer 601 while latching them with an inverted latching clock PCLKLART of the command address signals CA0 to CAk, and outputs a signal PMRSRB which turns to “L” level when signals PCAB0 to PCABk represent a MRS reset command. A command decode latch circuit (MRS) 603 decodes the signals PCAB0 to PCABk while latching them with the latching clock PCLKLART, and outputs a signal PMRSTT which turns to “H” level when the signals PCAB0 to PCABk represent a MRS command. The output signal PMRSTT from the command decode latch circuit (MRS) 603 is input to a control circuit 606 or the like for controlling various parts of the device. The output signal PMRSRB from the command decode latch circuit (MRS reset) 602 is input to a fuse latch generator (1) 604, the control circuit 606, and so on.

The fuse latch generator (1) 604 is supplied with the PMRSRB signal output by the command decode latch circuit (MRS reset) 602 and a signal VPUURB, and outputs signals PREB1, FSET1 and PRENB1. The signal VPUURB is a signal which becomes “L” level for a certain period of time during buildup of a power supply voltage, and is used for example for resetting various part of the device. That is, the signal VPUURB is a reset signal during power-up. The output signals PREB1 and FSET1 from the fuse latch generator (1) 604 are input to a fuse latch circuit block (1) 605, while the output signal PRENB1 is input to a subsequent fuse latch generator (2) 607. The fuse latch generator 607 is supplied with the signals PRENB1 and VPUURB, and outputs signals PREB2, FSET2 and PRENB2. The output signals PREB2 and FSET2 from the fuse latch generator (2) 607 are input to a fuse latch circuit block (2) 608, while the output signal PRENB2 is input to a fuse latch generator (3) 609. Likewise, the fuse latch generator (3) 609 is supplied with the signals PRENB2 and VPUURB and outputs signals PREB3 and FSET3 to a fuse latch circuit block (3) 610.

The circuit of the present embodiment, which operates in a time division manner, is composed of n (n is a number of divisions) sets of fuse latch generators and fuse latch circuit blocks. The circuit blocks are connected such that each circuit block operates in response to an output signal from the precedent circuit block in terms of time division and generates an output signal to the subsequent circuit block in terms of time division. Each of the figures in the parenthesis in the blocks of FIG. 6 indicates the sequential number of the time division which the generator or circuit block is associated with. Further, according to the circuit configuration of the present embodiment, each fuse latch circuit is formed by combination of a fuse latch generator and a fuse latch circuit block. Therefore, in the following description, each set of the fuse latch generator and fuse latch circuit block can be collectively referred to as the fuse latch circuit.

The circuit configuration shown in FIG. 6 is such that a signal PRENBn−1 output by a (n−1)-th fuse latch generator (not shown) is input to a fuse latch generator (n) 611, and output signals PREBn and FSETn output by the fuse latch generator (n) 611 are input to a fuse latch circuit block (n) 612. Although not shown in the figure, there are a plurality of command latch circuits and a plurality of circuits to be reset with the PMRSRB signal.

The semiconductor device of the present embodiment has n (n is an integer of two or more) sets of fuse latch circuits each consisting of a fuse latch generator for generating a control signal and a fuse latch circuit block for reading and latching the state of a fuse element. These n sets of fuse latch circuits sequentially operate in a time-division manner such that the time periods in which the respective fuse latch circuits perform precharge operation do not overlap with each other in the period from input of a command to reset the operation mode register until input of a command to set an operation mode in the operation mode register.

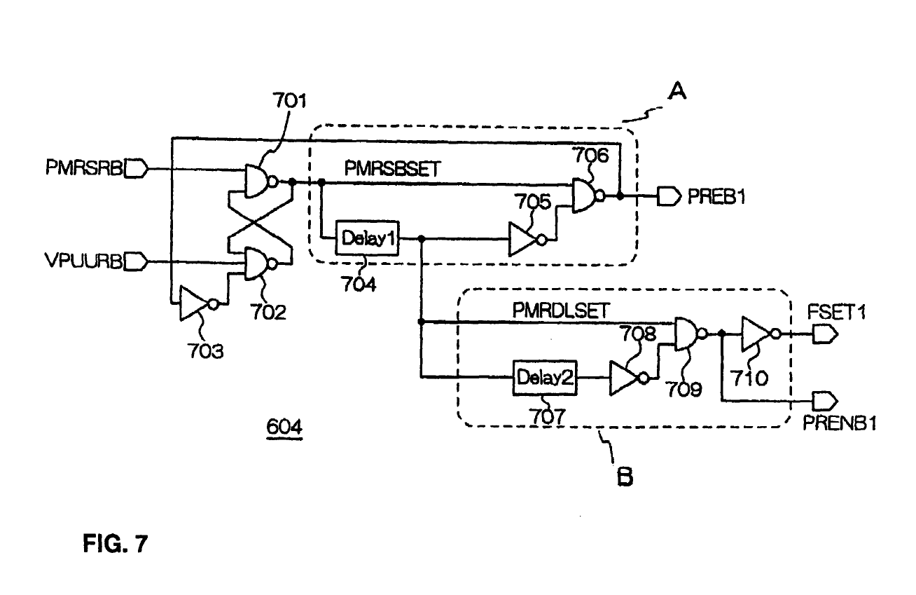

FIG. 7 shows a configuration example of the fuse latch generator (1) 604 shown in FIG. 6. The other fuse latch generators of FIG. 6, namely the fuse latch generator (2) 607, the fuse latch generator (3) 609, . . . , and the fuse latch generator (n) 611 also can be configured in the same manner. However, these other fuse latch generators, namely the fuse latch generator (2) 607, the fuse latch generator (3) 609, . . . , and the fuse latch generator (n) 611 are each supplied with a signal PRENB from a precedent fuse latch generator instead of an input signal PMRSRB. Further, the fuse latch generator (n) 611 does not output a signal PRENBn.

As shown in FIG. 7, the fuse latch generator (1) 604 includes a flip-flop circuit composed of NAN Ds 701 and 702 cross-connected to each other and an inverter 703, a delay circuit 704 for generating a delay of time Delay1, a one-shot pulse circuit A composed of an inverter 705 and a NAND 706, a delay circuit 707 for generating a delay of time Delay2, and a one-shot pulse circuit B composed of inverters 708, 710 and a NAND 709.

In this configuration, the NAND 701 is supplied with a signal PMRSRB and an output of the NAND 702, while the NAND 702 is supplied with a signal VPUURB, an output of the NAND 701, and an inverted signal obtained by inverting an output of the NAND 706 by the inverter 703. The output of the NAND 701 is set to “H” level when the signal PMRSRB is at “L” level, and is reset to “L” level when the signal VPUURB or the output of the inverter 703 is at “L” level.

The delay circuit 704 delays the output signal PMRSBSET from the NAND 701 by time Delay 1 and inputs the delayed signal to the inverter 705. The output signal PMRSBSET from the NAND 701 is also input to the NAND 706 together with an output of the inverter 705, and the NAND 706 outputs a signal PREB1.

The output signal PMRDLSET from the delay circuit 704 is also input to the delay circuit 707 and the NAND 709. The signal is delayed by time Delay 2 by the delay circuit 707 and the delayed signal is input to the NAND 709 via the inverter 708. The NAND 709 outputs a signal which becomes an output signal PRENB1 of the fuse latch generator (1) 604. On the other hand, an output of the NAND 709 is inverted by the inverter 710 to be output as an output signal FSET1.

As described above, the fuse latch generator (1) 604 is supplied with a command to reset the operation mode register and a reset signal during power-up, and outputs signals PREB1 and FSET1. The signal PREB1 is a signal for precharging, and the signal FSET1 is a signal for reading out the state of the fuse element.

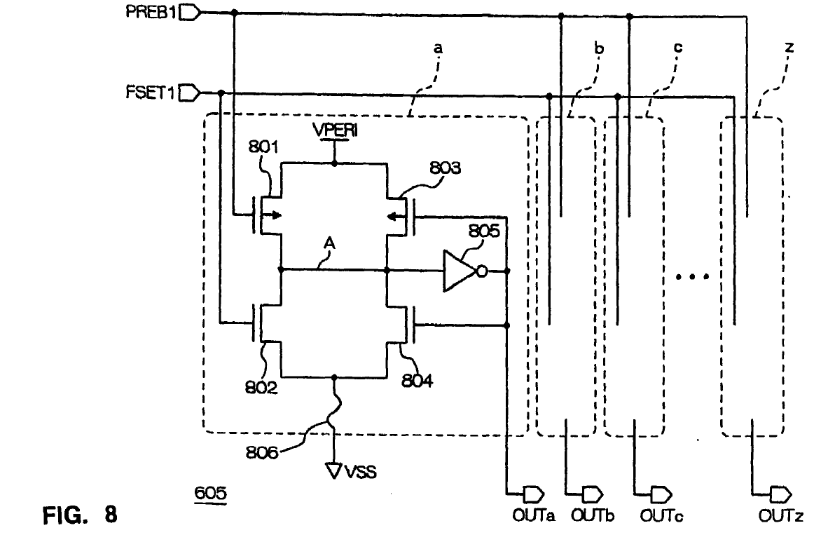

A configuration example of the fuse latch circuit block (1) 605 shown in FIG. 6 will be described with reference to FIG. 8. The other fuse latch circuit blocks in FIG. 6, namely the fuse latch circuit block (2) 608, the fuse latch circuit block (3) 610, . . . , and the fuse latch circuit block (n) 612 can also be configured in the same manner. Each of the fuse latch circuit blocks 605, 608, 610, . . . , 612 is composed of a plurality of basic fuse latch circuit block units, the number of which is variable according to the circuit configuration. The fuse latch circuit block (a) 605, as shown herein, has fuse latch circuit block units a to z.

The fuse latch circuit block (1) 605 shown in FIG. 8 is composed of the fuse latch circuit block units a to z. Each of the fuse latch circuit block units a to z has the same configuration as that shown in FIG. 2, and is composed of PMOS transistors 801, 803, NMOS transistors 802, 804, an inverter 805, and a fuse element 806. After latched, the fuse latch circuit block (1) 605 outputs the same number of signals as that of the fuse latch circuit block units. Specifically, the fuse latch circuit block (1) 605 outputs output signals OUTa to OUTz in the shown configuration. The fuse element 806, the PMOS transistors 801 and 803, the NMOS transistor 802 and 804 and the inverter 805 in FIG. 8 correspond to the fuse element FUSE, the PMOS transistors 33 and 34, the NMOS transistors 31 and 32, and the inverter 35 in FIG. 2, respectively. The signal PREB1, the signal FSET1 and the output signals OUTa to OUTz in FIG. 8 correspond to the signal PREB, the signal FSET and the output signal OUT in FIG. 2, respectively.

As described above, each fuse latch circuit block unit is composed of a PMOS transistor 801 for precharging the node A in response to a precharge signal, and a latch circuit portion for reading out and latching the state of a fuse element arranged therein onto the node A in response to a fuse set signal. In the following description, each fuse latch circuit block unit in FIG. 8 is abbreviated with latch circuit.

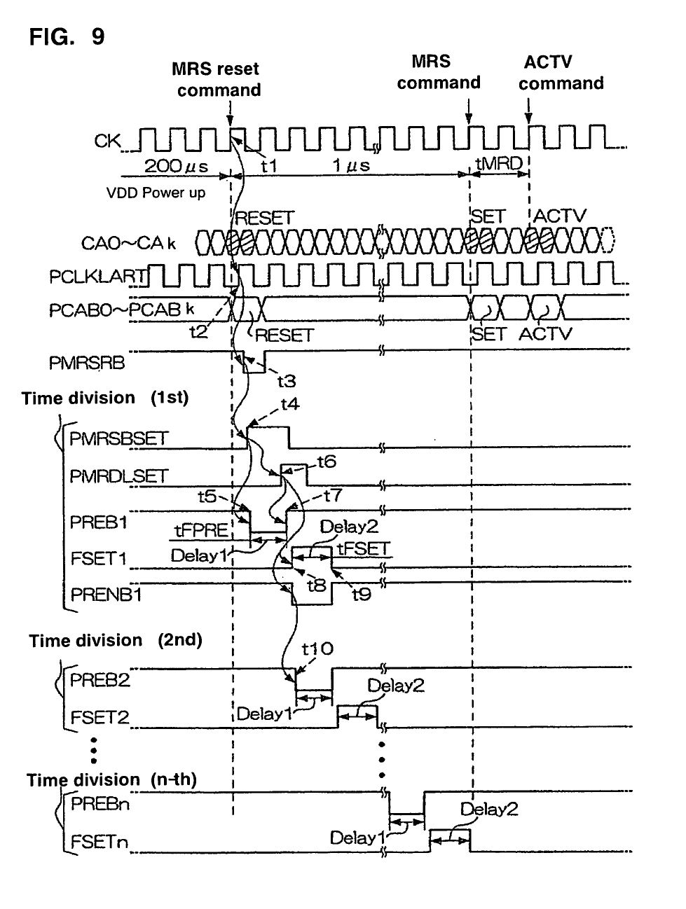

The operation of the present embodiment shown in FIG. 6 and so on will be described with reference to the timing chart of FIG. 9. The circuit of the present embodiment is triggered by a MRS reset command (mode register set reset command) to start fuse latching. The MRS reset command is a command externally input after a duration of 200 μs has elapsed after the power-on in which the power supply voltage VDD is sufficiently built up and the clock signal is stabilized, and is a command to reset a register for setting an operation mode of the memory. After a lapse of 1 μs or more from the input of the MRS reset command, the memory control is performed by using a MRS command, an ACTV command and so on.

The MRS reset command is determined by a combination of command address signals CA0 to CAk input from the command address pins shown in FIG. 6. The command address signals CA0 to CAk are input into the input buffer 601, inverted, and output as signals PCAB0 to PCABk. These output signals PCAB0 to PCABk are input to the command decode latch circuits 602, 603 and so on and output therefrom after being decoded and latched.

According to the present embodiment, when a MRS reset command is input (at time t1 in FIG. 9), the MRS resetting command decode latch circuit 602 is supplied with signals PCAB0 to PCABk and latched by a latching clock PCLKLART (at time t2). A MRS reset signal PMRSRB is output from the MRS resetting command decode latch circuit 602 (at time t3) and input to the fuse latch generator (1) 604. The MRS reset signal PMRSRB input to the fuse latch generator (1) 604 is at “L” level. A “H” level signal is output as a signal PMRSBSET by the flip-flop circuit composed of the NANDs 701 and 702 and so on of the fuse latch generator (1) 604 shown in FIG. 7 (at time t4). The signal PMRSBSET is passed through the one-shot pulse circuit A and output as an “L” level signal PREB1 signal (at time t5).

This output signal PREB1 is reset to “H” level by a signal PMRDLSET which has been branched from the signal PMRSBSET and has passed through the delay circuit 704 having a delay time Delay1 (at time t6 and t7). The signal PREB1 is a one-shot pulse signal having a pulse width of Delay1, and is input to the fuse latch circuit block (1) 605. In the fuse latch circuit block (1) 605, as described with reference to FIGS. 2 and 3 and so on, the nodes A in the latch circuits a to z shown in FIG. 8 are precharged within a period of time in which the signal PREB1 is at “L” level. This period of time in which the signal PREB1 is at “L” level corresponds to the first fuse precharge period tFPRE in FIG. 5.

On the other hand, the signal PMRDLSET delayed by time Delay1 is input at “H” level also to the one-shot pulse circuit B. The one-shot pulse circuit B outputs an output signal FSET1 having a pulse width of time Delay2 at “H” level (from time t8 to t9). The output signal FSET1 is input to the fuse latch circuit block (1) 605. The period of time in which this signal FSET1 is at “H” level corresponds to the first fuse setting period tFSET in FIG. 5.

As also described with reference to FIGS. 2 and 3, the fuse latch circuit block (1) 605 is supplied with the “H” level signal FSET1 as soon as the signal PREB1 is reset to “H” level. This means that the “H” level signal FSET1 is input upon completion of the precharge operation in the fuse latch circuits, whereby fuse information of the latch circuits a to z are read out simultaneously and output as signals OUTa to OUTz. As mentioned previously, a duration of about several nanoseconds is required as the time Delay1 for determining a fuse precharge period (tFPRE) and as the time Delay2 for determining a fuse setting period (tFSET).

According to the present embodiment, this series of operations is implemented for each of time-divided areas. In the circuit configuration shown in FIG. 6, the precharge operation for reading out all the fuse information in the fuse latch circuit block (1) 605 is completed before starting the setting operation for the subsequent time-divided area, namely the fuse latch circuit block (2) 608. The start signal PRENB1 for the subsequent time-divided area is an inverted signal of the signal FSET1 as shown in FIG. 7. In the present embodiment, the time division timing is set for the purpose of delaying the time at which through current is generated, and therefore the timing at which the precharge period ends is set as the starting point to implement the setting operation for the fuse circuit block in the subsequent area. Accordingly, a signal PRENB1 that is an inverted signal of the signal FSET1 is input at “L” level to the fuse latch generator (2) 607 in the subsequent area. In response to the signal PRENB1, operation is started in the fuse latch generator (2) 607 and the fuse latch circuit block (2) 608 in the same manner as in the fuse latch generator (1) 604 but with a delay of time Delay1 (at time t10). By repeating this for n times, the read-out of all the fuse data is completed.

As mentioned in the above, the number of divisions n can be maximized by using this configuration, and can be represented by (1 μs−tFSET)/tFPRE.

According to the present embodiment, a LPDDR2 memory, for example, is triggered by a MRS reset command instead of a conventionally used MRS command to start setting the fuse information. Further, the duration of time from the input of the MRS reset command to the input of the first MRS command is utilized effectively to implement the time-division operation. The implementation of the time-division operation reduces the through current, whereby it is made possible to set the fuse information stably within the initial period.

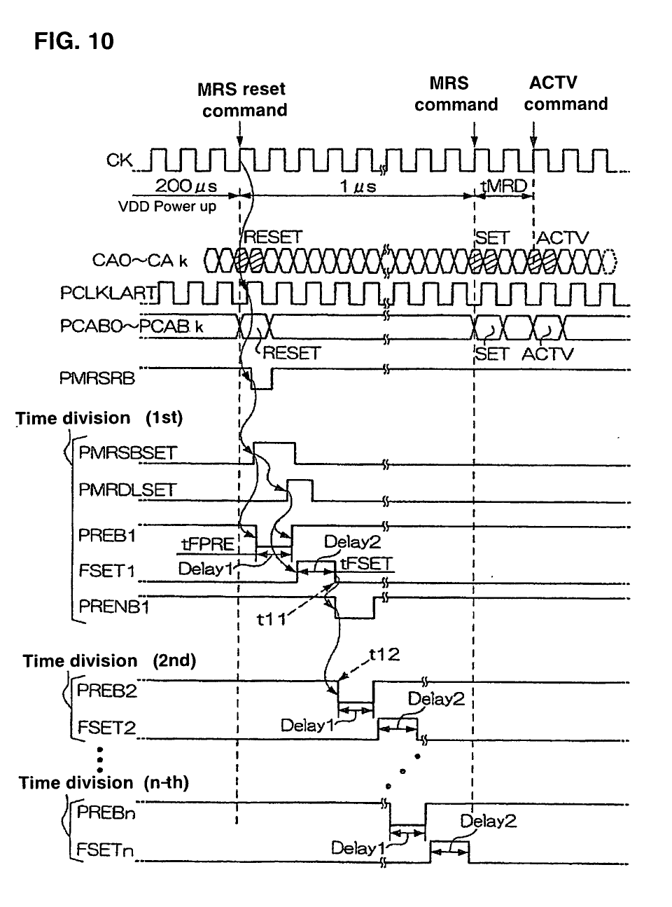

FIG. 10 is a timing chart showing a modification example of the embodiment described above. As shown in FIG. 10, the time-division operation is started by signals PMRSRB and PRENB1 to PRENB(n−1) as in FIG. 9, whereas the timing at which the operation is started is set to a time after the signal FSET1 is reset to “L” level (time t11). Thus, the setting operation for the subsequent fuse latch circuit block (2) is not started until the operation in the fuse latch circuit block (1) is completed completely (time t12). When the operation is performed in this manner, the number of divisions n is made smaller than that in the configuration of FIG. 9. Nevertheless, the fuse information can be read out in a more stable environment in the chip, and the effect of noise or the like can be reduced, resulting in improved circuit operation margin.

Although the present invention has been described in conjunction with a few preferred embodiments and examples thereof, this invention is not limited thereto. Obviously various modifications and variations of the configuration and particulars of this invention are possible to those skilled in the art without departing from the scope of the invention. For example, some or all of the plurality of fuse latch circuit blocks may be formed by a single latch circuit (formed by integrating the latch circuits a to z shown in FIG. 8). Further, the interval of the time-divided periods may be further enlarged to be greater than shown in FIG. 10.

What is claimed is:

1. A fuse latch circuit comprising:
a fuse latch generator which, when receiving a command to reset an operation mode register after power-on, outputs a precharge signal to control precharge operation for reading out a state of a fuse element, and a fuse set signal for reading out and latching the state of the fuse element after completion of the precharge operation; and
a latch circuit which, after performing the precharge operation in response to the precharge signal, reads out the state of the fuse element and latches that state in response to the fuse set signal.

2. The fuse latch circuit as claimed in claim 1, wherein the fuse latch generator is supplied with a command to reset the operation mode register and a reset signal during power-up, and outputs the precharge signal and then the fuse set signal subsequent to the precharge signal.

3. The fuse latch circuit as claimed in claim 1, wherein the latch circuit is composed of:
a transistor for precharging a node A in response to the precharge signal; and
a latch circuit portion which reads out a state of a fuse element provided therein onto the node A in response to the fuse set signal after completion of the precharge operation, and latches that state.

4. The fuse latch circuit as claimed in claim 1, comprising at least two fuse latch circuits each including the fuse latch generator and the fuse latch circuit block having the latch circuits, wherein the fuse latch circuits sequentially operate in a time division manner such that precharge operation periods of the respective fuse latch circuits do not overlap with each other within a period of time from input of a command to reset the operation mode register until input of a command to set an operation mode in the operation mode register.

5. The fuse latch circuit as claimed in claim 4, wherein the fuse latch generator of the first fuse latch circuit operating firstly after input of a command to reset the operation mode register is supplied with the command to reset the operation mode register and a reset signal during power-up, and outputs the precharge signal, the fuse set signal, and a start signal to start up the subsequent fuse latch circuit performing a next time-division operation.

6. The fuse latch circuit as claimed in claim 5, wherein the fuse latch generator of the subsequent fuse latch circuit is supplied with the start signal and the reset signal during power-up, and outputs the precharge signal and the fuse set signal.

7. The fuse latch circuit as claimed in claim 5, wherein the fuse latch generator of the first fuse latch circuit outputs, after completion of the precharge period of the first fuse latch circuit, the start signal to the fuse latch generator of the subsequent fuse latch circuit performing a next time-division operation.

8. The fuse latch circuit as claimed in claim 5, wherein the fuse latch generator of the first fuse latch circuit outputs, after completion of the precharge period and the fuse information setting period of the first fuse latch circuit, the start signal to the fuse latch generator of the subsequent fuse latch circuit performing a next time-division operation.

9. A semiconductor device comprising:
a fuse element for storing data as non-volatile data:
a command decode latch circuit which is supplied with a set command for setting the operation mode register or a reset command for resetting the operation mode register, and outputs a control signal in response to the reset command; and
a latch circuit for latching the data stored in the fuse element.

10. The semiconductor device as claimed in claim 9, wherein the command decode latch circuit is supplied with the reset command ahead of the set command.

11. The semiconductor device as claimed in claim 9, wherein the fuse element is composed of multiple fuse elements.

12. The semiconductor device as claimed in claim 11, further comprising multiple latch circuits corresponding to the multiple fuse elements, and a fuse latch generator for supplying the multiple latch circuits with a fuse control signal based on the control signal to operate in a time division manner.

13. The semiconductor device as claimed in claim 12, comprising n (n is an integer of two or more) sets of fuse latch circuits each including the fuse latch generator and a fuse latch circuit block having the latch circuits,
wherein the n sets of fuse latch circuits sequentially operate in a time division manner such that precharge operation periods of the respective fuse latch circuits do not overlap with each other within a period of time from input of the reset command until input of the set command.

14. The semiconductor device as claimed in claim 13, wherein:
the fuse latch generator of the first fuse latch circuit operating firstly after input of the reset command is supplied with a reset signal during power-up and the reset command as a start signal, and outputs a precharge signal and fuse set signal to the fuse latch circuit block of the first fuse latch circuit, and a start signal to the fuse latch generator of a second fuse latch circuit performing a next time-division operation;
the fuse latch circuit block of the first fuse latch circuit performs the precharge operation and reads out and latches the state of a fuse element in response to the input precharge signal and fuse set signal; and
the fuse latch generator of the second fuse latch circuit outputs, after completion of the precharge operation in at least the fuse latch circuit block of the first fuse latch circuit, a precharge signal and fuse set signal to the fuse latch circuit block of the second fuse latch circuit, in response to the start signal from the fuse latch generator of the first fuse latch circuit.

15. A fuse latch method wherein a precharge operation for reading out a state of a first fuse element is started when a command to reset an operation mode register is input after power-on, and after completion of the precharge operation, the state of the fuse element is read out and latched.

16. The fuse latch method as claimed in claim 15, wherein another precharge operation for reading out a state of a second fuse element is started after completion of the precharge operation for reading out the state of the first fuse element, so that the precharge operation periods for reading the states of the first and second fuse elements are differed from each other to realize a time-division operation.

17. The fuse latch method as claimed in claim 15, wherein a precharge operation for reading out a state of a second fuse element is started after the state of the first fuse element has been read out and latched, so that the precharge operation periods for reading out the states of the first and second fuse elements and fuse setting periods thereof are differed from each other to realize a time-division operation.
